(19) United States
(12) Patent Application Publication
(10) Pub. No.: US 2024/0389305 A1
(43) Pub. Date: Nov. 21, 2024

(54) SEMICONDUCTOR STRUCTURE AND MANUFACTURING METHOD THEREOF

(71) Applicant: Winbond Electronics Corp., Taichung City (TW)

(72) Inventors: Noriaki Ikeda, Kaohsiung City (TW); Chun-Sheng Yang, Taichung City (TW); Hsing-Hao Chen, Kaohsiung City (TW)

(73) Assignee: Winbond Electronics Corp., Taichung City (TW)

(21) Appl. No.: 18/639,992

(22) Filed: Apr. 19, 2024

(30) Foreign Application Priority Data
May 19, 2023 (TW) 112118780

(51) Int. Cl. H10B 12/00

(52) U.S. Cl. CPC H10B 12/482; H10B 12/0335; H10B 12/485

(57) ABSTRACT

A semiconductor structure including the following components is provided. Stack structures are located on a substrate and separated from each other. Isolation layers are located on the sidewalls of the stack structures. A contact is located on the substrate between two adjacent isolation layers. A landing pad is located on the contact. The landing pad is located on one of the two adjacent isolation layers. There is an opening on one side of the landing pad. A first dielectric layer is located in the opening. A porous dielectric layer is located between the first dielectric layer and the landing pad. The top surface of the porous dielectric layer is lower than the top surface of the landing pad and the top surface of the first dielectric layer to form a recess between the landing pad and the first dielectric layer. The recess exposes the sidewall of the landing pad.

### CROSS-REFERENCE TO RELATED APPLICATION

This application claims the priority benefit of Taiwan application serial no. 112118780, filed on May 19, 2023. The entirety of the above-mentioned patent application is hereby incorporated by reference herein and made a part of this specification.

### BACKGROUND

### Technical Field

The invention relates to a semiconductor structure and a manufacturing method thereof, and particularly relates to a semiconductor structure capable of improving an electrical performance of a semiconductor device and a manufacturing method thereof.

### Description of Related Art

In the semiconductor device, the landing pad is used as an electrical connection component. For example, the conductive component can land on the landing pad. Therefore, if the resistance value between the conductive component and the landing pad can be further reduced, it will help to improve the electrical performance of the semiconductor device.

### SUMMARY

The invention provides a semiconductor structure and a manufacturing method thereof, which can effectively improve the electrical performance of the semiconductor device.

The invention provides a semiconductor structure, which includes a substrate, stack structures, isolation layers, a contact, a landing pad, a first dielectric layer, and a porous dielectric layer. The stack structures are located on the substrate and separated from each other. The isolation layers are located on the sidewalls of the stack structures. The contact is located on the substrate between two adjacent isolation layers. The landing pad is located on the contact. The landing pad is located on one of the two adjacent isolation layers. There is an opening on one side of the landing pad. The first dielectric layer is located in the opening. The porous dielectric layer is located between the first dielectric layer and the landing pad. The top surface of the porous dielectric layer is lower than the top surface of the landing pad and the top surface of the first dielectric layer to form a recess between the landing pad and the first dielectric layer. The recess exposes the sidewall of the landing pad.

The invention provides a manufacturing method of a semiconductor structure, which includes the following steps. A substrate is provided. Stack structures are formed on the substrate. The stack structures are separated from each other. Isolation layers are formed on the sidewalls of the stack structures. A contact is formed on the substrate between two adjacent isolation layers. A landing pad is formed on the contact. The landing pad is located on one of the two adjacent isolation layers. There is an opening on one side of the landing pad. A first dielectric layer is formed in the opening. A porous dielectric layer is formed between the first dielectric layer and the landing pad. The top surface of the porous dielectric layer is lower than the top surface of the landing pad and the top surface of the first dielectric layer to form a recess between the landing pad and the first dielectric layer. The recess exposes the sidewall of the landing pad.

Based on the above description, in the semiconductor structure and the manufacturing method thereof according to the invention, the top surface of the porous dielectric layer is lower than the top surface of the landing pad and the top surface of the first dielectric layer to form the recess between the landing pad and the first dielectric layer. The recess exposes the sidewall of the landing pad. Therefore, the conductive component (e.g., the electrode of the capacitor) subsequently formed on the landing pad can contact the top surface and the sidewall of the landing pad. In this way, the contact area between the conductive component (e.g., the electrode of the capacitor) and the landing pad can be increased, thereby reducing the resistance value, so that the electrical performance of the semiconductor device (e.g., memory) can be improved. In addition, the process of the porous dielectric layer can provide the effect of hydrogen sintering (H₂ sintering) treatment, so the lattice defects can be effectively repaired, thereby improving the electrical performance of the semiconductor device (e.g., memory).

In order to make the aforementioned and other objects, features and advantages of the invention comprehensible, several exemplary embodiments accompanied with drawings are described in detail below.

### BRIEF DESCRIPTION OF THE DRAWINGS

The accompanying drawings are included to provide a further understanding of the invention, and are incorporated in and constitute a part of this specification. The drawings illustrate embodiments of the invention and, together with the description, serve to explain the principles of the invention.

FIG. 1A to FIG. 1F are cross-sectional views of a manufacturing process of a semiconductor structure according to some embodiments of the invention.

FIG. 2 is a top view of a semiconductor structure according to some embodiments of the invention.

### DESCRIPTION OF THE EMBODIMENTS

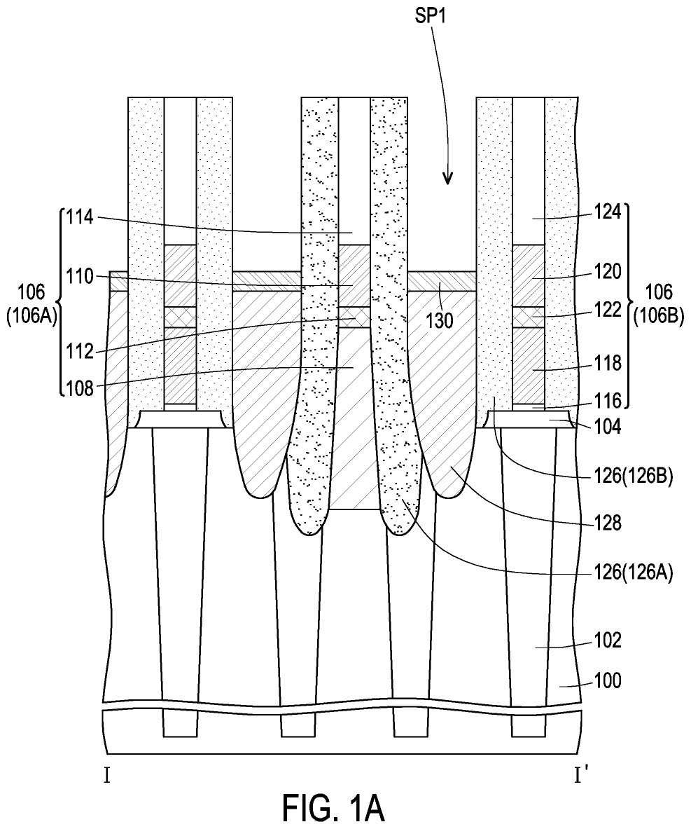

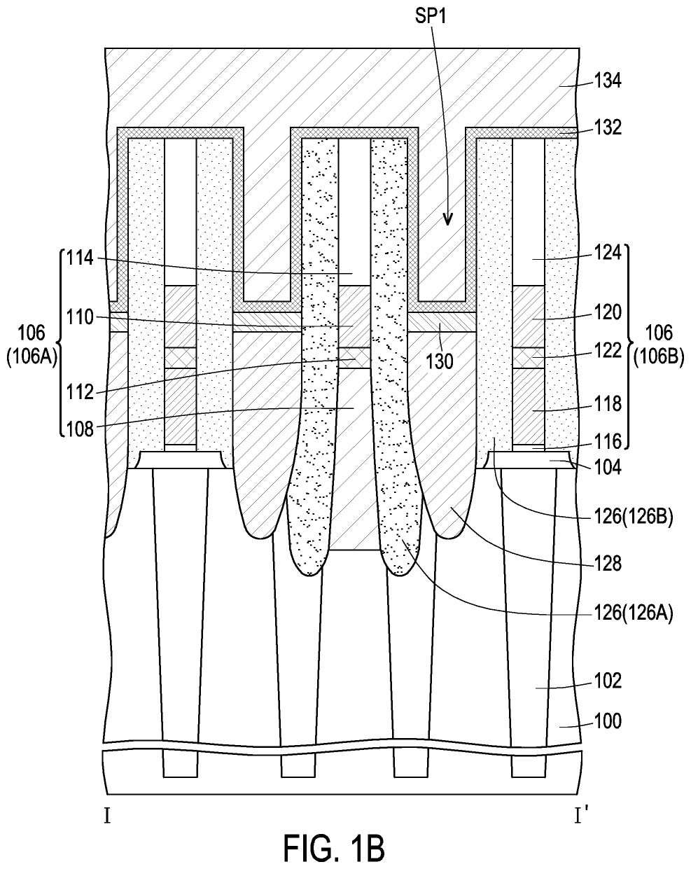

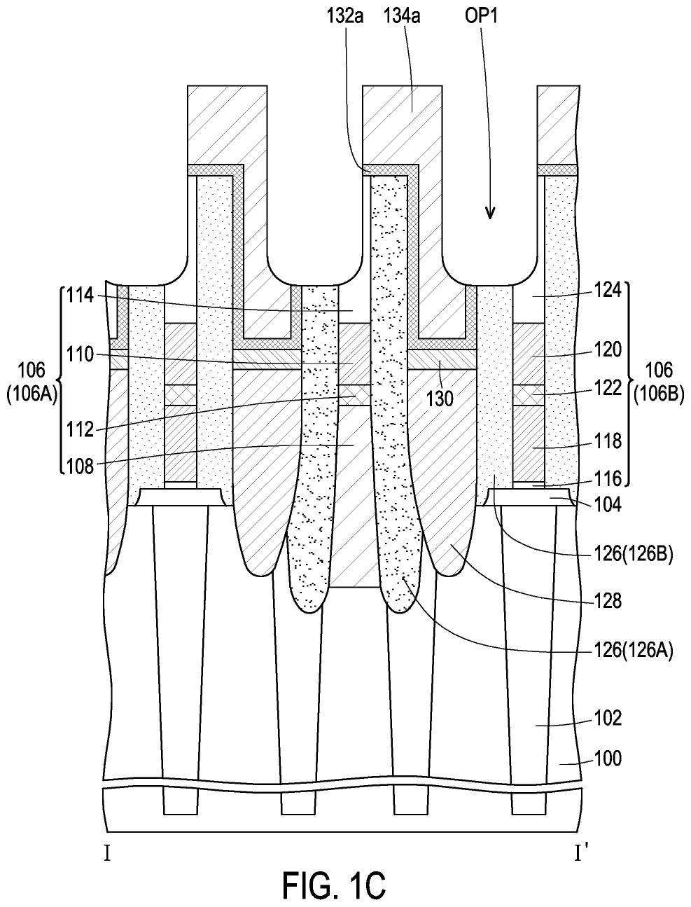

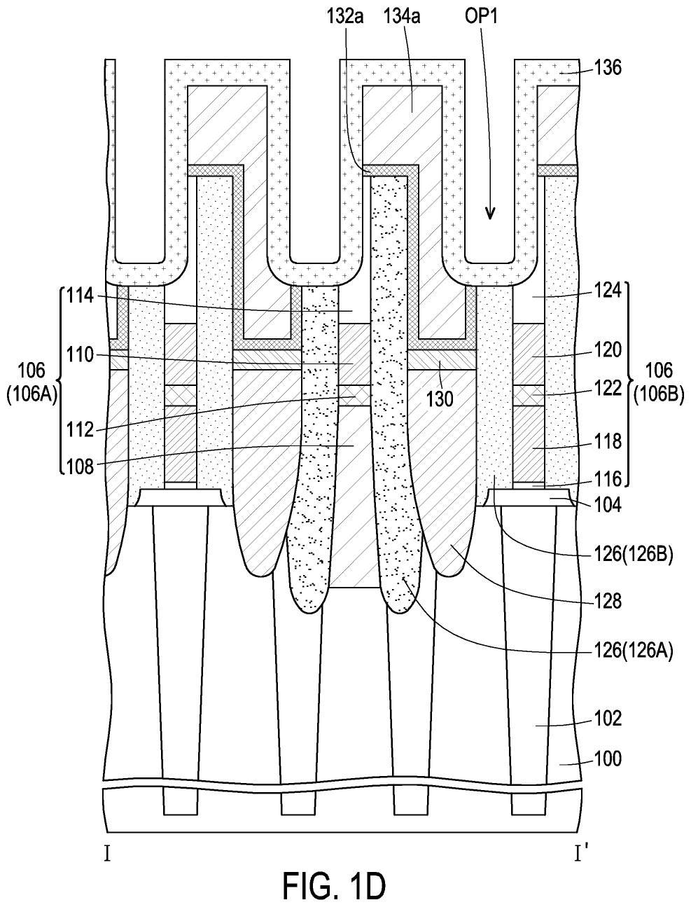

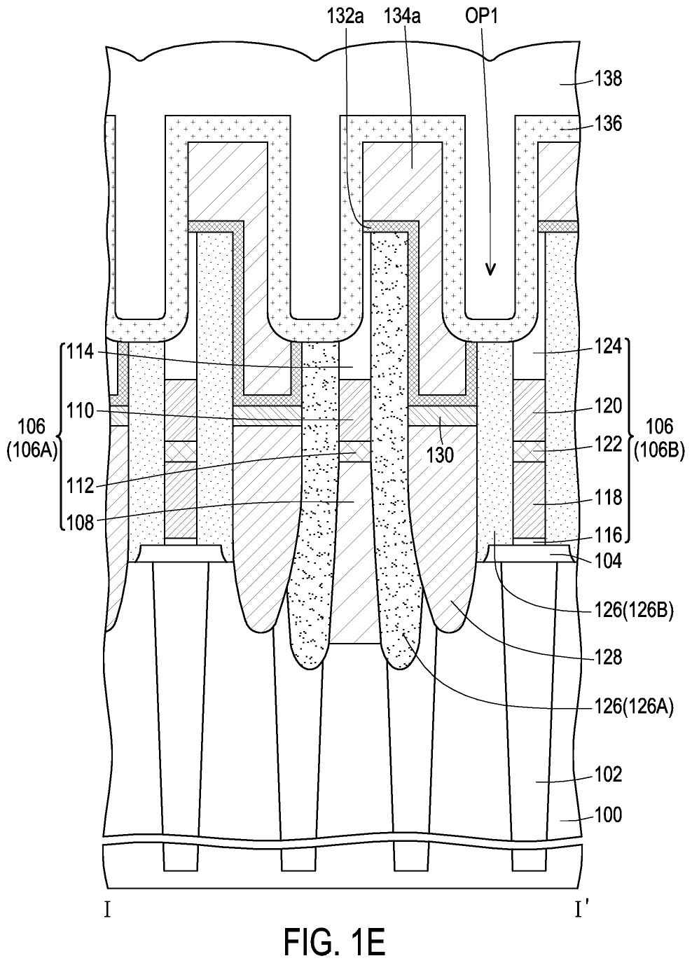

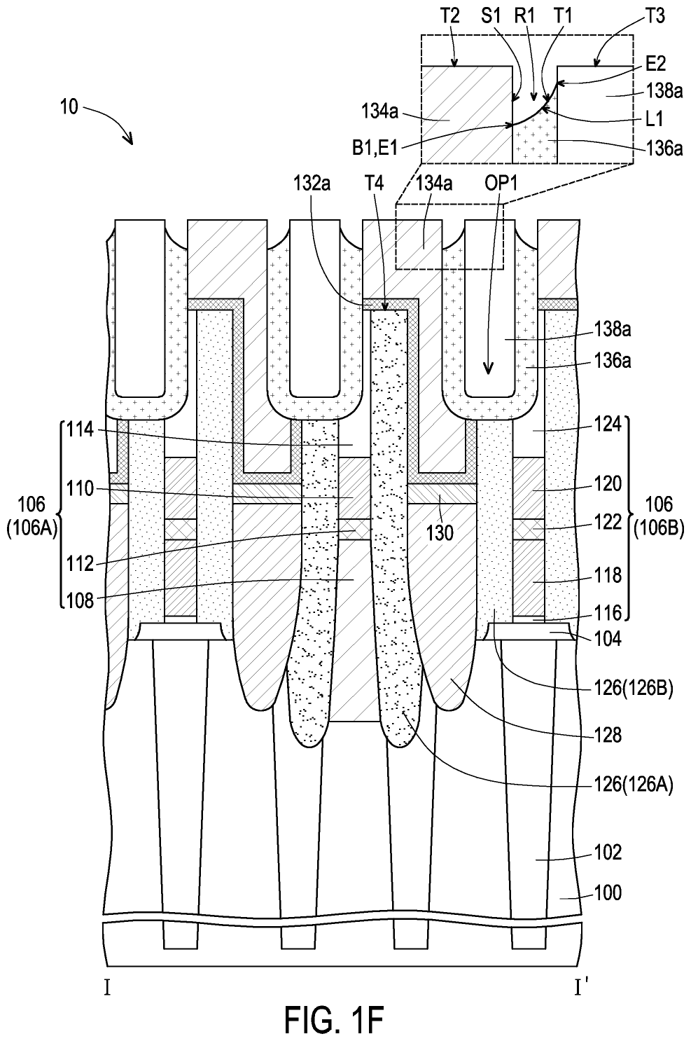

Referring to FIG. 1A, a substrate 100 is provided. The substrate 100 may be a semiconductor substrate such as a silicon substrate. Furthermore, an isolation structure 102 may be formed in the substrate 100. The isolation structure 102 may be a shallow trench isolation (STI) structure. The material of the isolation structure 102 may include oxide (e.g., silicon oxide). In addition, although not shown in the figure, other required components (e.g., doped regions and/or buried word line structures) may be formed in the substrate 100.

A dielectric layer 104 is formed on the substrate 100. The dielectric layer 104 may be a single-layer structure or a multilayer structure. The material of the dielectric layer 104 may include oxide (e.g., silicon oxide).

Stack structures 106 are formed on the substrate 100. The stack structures 106 are separated from each other. The stack structures 106 may include a bit line stack structure 106A and a conductive line stack structure 106B. The bit line stack structure 106A may include a bit line contact 108 and a bit line 110. The bit line contact 108 is located on the substrate 100. The material of the bit line contact 108 may include a conductive material such as doped polysilicon. The bit line 110 is located on the bit line contact 108. The material of the bit line 110 may include a conductive material such as tungsten. In some embodiments, the bit line stack structure 106A may further include a barrier layer 112 and a hard mask layer 114. The barrier layer 112 is located between the bit line contact 108 and the bit line 110. The material of the barrier layer 112 may include titanium, titanium nitride, or a combination thereof. The hard mask layer 114 is located on the bit line 110. The hard mask layer 114 may be a single-layer structure or a multilayer structure. The material of the hard mask layer 114 may include nitride (e.g., silicon nitride).

The conductive line stack structure 106B may include a dielectric layer 116, a conductive layer 118, and a conductive layer 120. The dielectric layer 116 is located on the substrate 100. The dielectric layer 116 may be located on the dielectric layer 104. The material of the dielectric layer 116 may include oxide (e.g., silicon oxide). The conductive layer 118 is located on the dielectric layer 116. The material of the conductive layer 118 may include a conductive material such as doped polysilicon. The conductive layer 120 is located on the conductive layer 118. The material of the conductive layer 120 may include a conductive material such as tungsten. In some embodiments, the conductive layer 120 and the bit line 110 may be simultaneously formed by the same process. In some embodiments, the conductive line stack structure 106B may further include a barrier layer 122 and a hard mask layer 124. The barrier layer 122 is located between the conductive layer 118 and the conductive layer 120. The material of the barrier layer 122 may include titanium, titanium nitride, or a combination thereof. In some embodiments, the barrier layer 122 and the barrier layer 112 may be simultaneously formed by the same process. The hard mask layer 124 is located on the conductive layer 120. The hard mask layer 124 may be a single-layer structure or a multilayer structure. The material of the hard mask layer 124 may include nitride (e.g., silicon nitride). In some embodiments, the hard mask layer 124 and the hard mask layer 114 may be simultaneously formed by the same process.

Then, isolation layers 126 are formed on the sidewalls of the stack structures 106. The isolation layers 126 may include an isolation layer 126A and an isolation layer 126B. The isolation layer 126A is located on the sidewall of the bit line stack structure 106A. A portion of the isolation layer 126A may be located in the substrate 100. The isolation layer 126A may be a single-layer structure or a multilayer structure. The material of the isolation layer 126A may include oxide (e.g., silicon oxide), nitride (e.g., silicon nitride), or a combination thereof. The isolation layer 126B is located on the sidewall of the conductive line stack structure 106B. The isolation layer 126B may be a single-layer structure or a multilayer structure. The material of the isolation layer 126B may include oxide (e.g., silicon oxide), nitride (e.g., silicon nitride), or a combination thereof. In some embodiments, the isolation layer 126A and the isolation layer 126B may be multilayer structures, and a portion of the layers in the isolation layer 126A and a portion of the layers in the isolation layer 126B may be simultaneously formed by the same process.

A contact 128 is formed on the substrate 100 between two adjacent isolation layers 126. In some embodiments, the contact 128 may be used as a capacitor contact. For example, the contact 128 may be formed on the substrate 100 between the isolation layer 126A and the isolation layer 126B. The contact 128 may be formed in the space SP1 between the two adjacent isolation layers 126 (e.g., isolation layer 126A and isolation layer 126B). The material of the contact 128 may include a conductive material such as doped polysilicon. In some embodiments, a metal silicide layer 130 may be formed on the contact 128. The material of the metal silicide layer 130 may include cobalt silicide (CoSi) or nickel silicide (NiSi). In some embodiments, the metal silicide layer 130 may be formed by a self-aligned silicide (salicide) process.

Referring to FIG. 1B, a barrier material layer 132 may be formed on the stack structures 106, the isolation layers 126, and the contact 128 and in the space SP1. In some embodiments, the barrier material layer 132 may be formed on the metal silicide layer 130. The material of the barrier material layer 132 may include titanium, titanium nitride, or a combination thereof. The method of forming the barrier material layer 132 may include a chemical vapor deposition (CVD) method or a physical vapor deposition (PVD) method.

A landing pad material layer 134 may be formed on the stack structures 106, the isolation layers 126, and the contact 128. The landing pad material layer 134 may fill the space SP1 between the two adjacent isolation layers 126. In some embodiments, the landing pad material layer 134 may be formed on the barrier material layer 132. The material of the landing pad material layer 134 may be a conductive material such as a metal-containing material (e.g., tungsten). The method of forming the landing pad material layer 134 may include a CVD method or a PVD method.

Referring to FIG. 1C, a patterning process may be performed on the landing pad material layer 134 and the barrier material layer 132 to form a landing pad 134a, a the barrier layer 132a, and an opening OP1. In some embodiments, the landing pad material layer 134 and the barrier material layer 132 may be patterned by a lithography process and an etching process (e.g., dry etching process).

By the above method, the landing pad 134a may be formed on the contact 128. The landing pad 134a is located on one of the two adjacent isolation layers 126. There is an opening OP1 on one side of the landing pad 134a. In some embodiments, the landing pad 134a may be further located on the stack structure 106 and the metal silicide layer 130. The opening OP1 may expose the landing pad 134a, the isolation layer 126, and the stack structure 106.

In addition, the barrier layer 132a may be formed between the landing pad 134a and the isolation layer 126 by the above method. In some embodiments, the barrier layer 132a may be further formed between the landing pad 134a and the metal silicide layer 130 and between the landing pad 134a and the stack structure 106.

Referring to FIG. 1D, a porous dielectric material layer 136 may be formed in the opening OP1. The porous dielectric material layer 136 may be formed on the landing pad 134a, the barrier layer 132a, the stack structure 106, and the isolation layer 126. In addition, the process of the porous dielectric material layer 136 can provide the effect of hydrogen sintering (H₂ sintering) treatment, so the lattice defects can be effectively repaired, thereby improving the electrical performance of the semiconductor device (e.g., memory). The material of the porous dielectric material layer 136 may include nitride (e.g., silicon nitride). The method of forming the porous dielectric material layer 136 may include an atomic layer deposition (ALD) method.

Referring to FIG. 1E, a dielectric material layer 138 may be formed on the porous dielectric material layer 136. The dielectric material layer 138 may fill the opening OP1. The material of the dielectric material layer 138 may include nitride (e.g., silicon nitride). A method of forming the dielectric material layer 138 may include an ALD method.

Referring to FIG. 1F, an etch-back process may be performed on the dielectric material layer 138 and the porous dielectric material layer 136 to form a dielectric layer 138a and a porous dielectric layer 136a and to expose the landing pad 134a. The etch-back process may be a dry etching process. In the etch-back process, the etching rate of the porous dielectric material layer 136 may be greater than the etching rate of the dielectric material layer 138. In the etch-back process, the etching rate of the porous dielectric material layer 136 may be 1.1 times to 1.5 times the etching rate of the dielectric material layer 138.

By the above method, the dielectric layer 138a may be formed in the opening OP1, and the porous dielectric layer 136a may be formed between the dielectric layer 138a and the landing pad 134a. The top surface T1 of the porous dielectric layer 136a is lower than the top surface T2 of the landing pad 134a and the top surface T3 of the dielectric layer 138a to form a recess R1 between the landing pad 134a and the dielectric layer 138a. The recess R1 exposes the sidewall S1 of the landing pad 134a. Therefore, the conductive component (e.g., the electrode of the capacitor) subsequently formed on the landing pad 134a can contact the top surface T2 and the sidewall S1 of the landing pad 134a. In this way, the contact area between the conductive component (e.g., the electrode of the capacitor) and the landing pad 134a can be increased, thereby reducing the resistance value, so that the electrical performance of the semiconductor device (e.g., memory) can be improved.

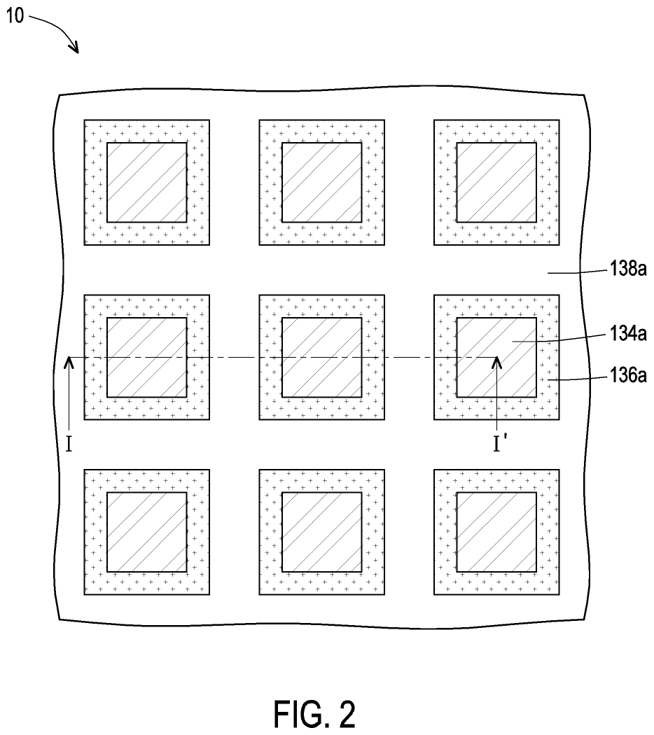

The bottom B1 of the recess R1 may be higher than the top surface T4 of the isolation layer 126. The cross-sectional profile of the recess R1 may include a curved line L1. The curved line L1 may have a first end E1 and a second end E2. The first end E1 may be adjacent to the landing pad 134a. The second end E2 may be adjacent to the dielectric layer 138a. The second end E2 may be higher than the first end E1. As shown in FIG. 2, the top-view pattern of the recess R1 may surround the top-view pattern of the landing pad 134a, and the top-view pattern of the dielectric layer 138a may surround the top-view pattern of the recess R1.

In subsequent processes, other required components (e.g., capacitors) may be formed to complete the fabrication of the semiconductor device (e.g., memory), and the description thereof is omitted here.

Hereinafter, the semiconductor structure 10 of the present embodiment will be described with reference to FIG. 1F and FIG. 2. In addition, although the method for forming the semiconductor structure 10 is described by taking the above method as an example, the invention is not limited thereto.

Referring to FIG. 1F and FIG. 2, the semiconductor structure 10 includes the substrate 100, the stack structures 106, the isolation layers 126, the contact 128, the landing pad 134a, the dielectric layer 138a, and the porous dielectric layer 136a. In some embodiments, the semiconductor structure 10 may be a memory structure such as a dynamic random access memory (DRAM) structure. The stack structures 106 are located on the substrate 100 and separated from each other. The isolation layers 126 are located on the sidewalls of the stack structures 106. The contact 128 is located on the substrate 100 between two adjacent isolation layers 126. The landing pad 134a is located on the contact 128. The landing pad 134a is located on one of the two adjacent isolation layers 126. There is an opening OP1 on one side of the landing pad 134a. The dielectric layer 138a is located in the opening OP1. The porous dielectric layer 136a is located between the dielectric layer 138a and the landing pad 134a. The top surface T1 of the porous dielectric layer 136a is lower than the top surface T2 of the landing pad 134a and the top surface T3 of the dielectric layer 138a to form a recess R1 between the landing pad 134a and the dielectric layer 138a. The recess R1 exposes the sidewall S1 of the landing pad 134a. In addition, the semiconductor structure 10 may further include a barrier layer 132a. The barrier layer 132a is located between the landing pad 134a and the contact 128, between the landing pad 134a and one of the two adjacent isolation layers 126, and between the landing pad 134a and the other of the two adjacent isolation layers 126. In some embodiments, the barrier layer 132a may be located between the landing pad 134a and the metal silicide layer 130.

Furthermore, the remaining components in the semiconductor structure 10 may refer to the description of the above embodiments. Moreover, the details (e.g., the material and the forming method) of the components in the semiconductor structure 10 have been described in detail in the above embodiments, and the description thereof is not repeated here.

Based on the above embodiments, in the semiconductor structure 10 and the manufacturing method thereof, the top surface T1 of the porous dielectric layer 136a is lower than the top surface T2 of the landing pad 134a and the top surface T3 of the dielectric layer 138a to form a recess R1 between the landing pad 134a and the dielectric layer 138a. The recess R1 exposes the sidewall S1 of the landing pad 134a. Therefore, the conductive component (e.g., the electrode of the capacitor) subsequently formed on the landing pad 134a can contact the top surface T2 and the sidewall S1 of the landing pad 134a. In this way, the contact area between the conductive component (e.g., the electrode of the capacitor) and the landing pad 134a can be increased, thereby reducing the resistance value, so that the electrical performance of the semiconductor device (e.g., memory) can be improved. In addition, the process of the porous dielectric layer 136a (e.g., the process of the porous dielectric material layer 136) can provide the effect of hydrogen sintering (H₂ sintering) treatment, so the lattice defects can be effectively repaired, thereby improving the electrical performance of the semiconductor device (e.g., memory).

Although the invention has been described with reference to the above embodiments, it will be apparent to one of ordinary skill in the art that modifications to the described embodiments may be made without departing from the spirit of the invention. Accordingly, the scope of the invention is defined by the attached claims not by the above detailed descriptions.

What is claimed is:

1. A semiconductor structure, comprising:
a substrate;
stack structures located on the substrate and separated from each other;
isolation layers located on sidewalls of the stack structures;
a contact located on the substrate between two adjacent isolation layers;
a landing pad located on the contact, wherein the landing pad is located on one of the two adjacent isolation layers, and there is an opening on one side of the landing pad;
a first dielectric layer located in the opening; and
a porous dielectric layer located between the first dielectric layer and the landing pad, wherein a top surface of the porous dielectric layer is lower than a top surface of the landing pad and a top surface of the first dielectric layer to form a recess between the landing pad and the first dielectric layer, and the recess exposes a sidewall of the landing pad.

2. The semiconductor structure according to claim 1, wherein a bottom of the recess is higher than top surfaces of the isolation layers.

3. The semiconductor structure according to claim 1, wherein a top-view pattern of the recess surrounds a top-view pattern of the landing pad.

4. The semiconductor structure according to claim 1, wherein a top-view pattern of the first dielectric layer surrounds a top-view pattern of the recess.

5. The semiconductor structure according to claim 1, wherein
a cross-sectional profile of the recess comprises a curved line,
the curved line has a first end and a second end,
the first end is adjacent to the landing pad,
the second end is adjacent to the first dielectric layer, and
the second end is higher than the first end.

6. The semiconductor structure according to claim 1, further comprising:
a barrier layer located between the landing pad and the contact, between the landing pad and one of the two adjacent isolation layers, and between the landing pad and the other of the two adjacent isolation layers.

7. The semiconductor structure according to claim 1, wherein the stack structures comprise a bit line stack structure and a conductive line stack structure.

8. The semiconductor structure according to claim 7, wherein the bit line stack structure comprises:
a bit line contact located on the substrate; and
a bit line located on the bit line contact.

9. The semiconductor structure according to claim 8, wherein the bit line stack structure further comprises:
a barrier layer located between the bit line contact and the bit line; and
a hard mask layer located on the bit line.

10. The semiconductor structure according to claim 7, wherein the conductive line stack structure comprises:
a second dielectric layer located on the substrate;
a first conductive layer located on the second dielectric layer; and
a second conductive layer located on the first conductive layer.

11. The semiconductor structure according to claim 10, wherein the conductive line stack structure further comprises:
a barrier layer located between the first conductive layer and the second conductive layer; and
a hard mask layer located on the second conductive layer.

12. The semiconductor structure according to claim 7, wherein the isolation layers comprise:
a first isolation layer located on a sidewall of the bit line stack structure; and
a second isolation layer located on a sidewall of the conductive line stack structure.

13. A manufacturing method of a semiconductor structure, comprising:
providing a substrate;
forming stack structures on the substrate, wherein the stack structures are separated from each other;
forming isolation layers on sidewalls of the stack structures;
forming a contact on the substrate between two adjacent isolation layers;
forming a landing pad on the contact, wherein the landing pad is located on one of the two adjacent isolation layers, and there is an opening on one side of the landing pad;
forming a first dielectric layer in the opening; and
forming a porous dielectric layer between the first dielectric layer and the landing pad, wherein a top surface of the porous dielectric layer is lower than a top surface of the landing pad and a top surface of the first dielectric layer to form a recess between the landing pad and the first dielectric layer.

14. The manufacturing method of the semiconductor structure according to claim 13, wherein a method of forming the landing pad and the opening comprises:
forming a landing pad material layer on the stack structures, the isolation layers, and the contact, wherein the landing pad material layer fills a space between the two adjacent isolation layers; and
performing a patterning process on the landing pad material layer to form the landing pad and the opening, wherein
the opening exposes the landing pad, the other of the two adjacent isolation layers, and one of the stack structures.

15. The manufacturing method of the semiconductor structure according to claim 13, wherein a method of forming the first dielectric layer and the porous dielectric layer comprises:
forming a porous dielectric material layer in the opening;
forming a dielectric material layer on the porous dielectric material layer; and
performing an etch-back process on the dielectric material layer and the porous dielectric material layer to form the first dielectric layer and the porous dielectric layer and to expose the landing pad.

16. The manufacturing method of the semiconductor structure according to claim 15, wherein in the etch-back process, an etching rate of the porous dielectric material layer is greater than an etching rate of the dielectric material layer.

17. The manufacturing method of the semiconductor structure according to claim 15, wherein in the etch-back process, an etching rate of the porous dielectric material layer is 1.1 times to 1.5 times an etching rate of the dielectric material layer.

18. The manufacturing method of the semiconductor structure according to claim 15, wherein a material of the porous dielectric material layer and a material of the dielectric material layer comprise nitride.

19. The manufacturing method of the semiconductor structure according to claim 15, wherein a method of forming the dielectric material layer comprises an atomic layer deposition method.

20. The manufacturing method of the semiconductor structure according to claim 13, further comprising:
forming a metal silicide layer on the contact; and
forming a barrier layer between the landing pad and the metal silicide layer.
